(19) United States
(12) Patent Application Publication
(10) Pub. No.: US 2011/0303931 A1
(43) Pub. Date: Dec. 15, 2011

(54) SEMICONDUCTOR LIGHT EMITTING DIODE AND METHOD FOR FABRICATING THE SAME

(76) Inventors: Ho-Jae KANG, Seoul (KR); Da-Woon Jung, Bupyeong-Gu (KR); Jong-Bin Kim, Paju (KR); Hyung-Sun Hwang, Paju (KR); Chung-Hoon Park, Hanam (KR)

(21) Appl. No.: 12/977,502

(22) Filed: Dec. 23, 2010

(30) Foreign Application Priority Data
Jun. 10, 2010 (KR) 10-2010-0055034

(51) Int. Cl. H01L 33/32; H01L 33/40

(52) U.S. Cl. 257/94; 438/47; 257/E33.025; 257/E33.028

(57) ABSTRACT

Disclosed are a semiconductor light emitting diode and a method for fabricating the same. The method comprises forming a crystalline nitride semiconductor layer on a substrate, forming an amorphous layer and a crystalline nitride semiconductor layer on the nitride semiconductor layer, forming an n-type nitride semiconductor layer on the crystalline nitride semiconductor layer, forming an active layer on the n-type nitride semiconductor layer, and forming a p-type nitride semiconductor layer on the active layer.

### CROSS-REFERENCE TO RELATED APPLICATION

Pursuant to 35 U.S.C. §119(a), this application claims the benefit of earlier filing date and right of priority to Korean Application 10-2010-0055034, filed on Jun. 10, 2010, the content of which is incorporated by reference herein in its entirety for all purposes as if fully set forth herein.

### BACKGROUND OF THE INVENTION

1. Field of the Invention

The present invention relates to a light emitting diode, and particularly, to a semiconductor light emitting diode (LED) having an improved epitaxial layer, and a method for fabricating the same.

2. Background of the Invention

Generally, a light emitting diode (LED) is a semiconductor device used to transmit and receive an electric signal after converting the electric signal into an infrared ray, a visible ray, or light with using characteristics of a compound semiconductor, such as re-coupling between electrons and holes.

This LED is generally applied to home electronics, remote controllers, electronic display boards, display devices, each kind of automatic devices, optical communications, and is largely categorized into an infrared emitting diode (IRED) and a visible light emitting diode (VLED).

In the LED, a frequency (or wavelength) of emitted light is a band gap function of a material used to a semiconductor device. In case of using a semiconductor material having a narrow band gap, photons having low energy and a long wavelength are generated. On the other hand, in case of using a semiconductor material having a wide band gap, photons having a short wavelength are generated. Accordingly, a semiconductor material of the LED is selected according to a type of light to be emitted.

For instance, a red LED uses AlGaInP, and a blue LED uses silicone carbide (SiC) and □-group nitride-based semiconductor, especially, gallium nitride (GaN).

Here, the gallium-based LED can not form a bulk single crystal of GaN. Accordingly, a substrate suitable for growth of a GaN crystal has to be used. As the substrate, sapphire is mainly used.

The conventional semiconductor LED using a sapphire substrate and a method for fabricating the same will be explained as follows.

FIG. 1 is a sectional view showing a structure of a semiconductor light emitting diode (LED) in accordance with the related art, and FIG. 2 is a sectional view schematically showing growth defects occurring when an epitaxial layer of a semiconductor LED grows in accordance with the related art.

As shown in FIG. 1, the semiconductor LED 10 comprises a sapphire substrate 11, a buffer layer 13 formed on the sapphire substrate 11, an epitaxial layer 15 formed of an un-doped semiconductor, an n-type nitride semiconductor layer 17, an active layer 19 having a multi quantum well structure, and a p-type nitride semiconductor layer 21.

A transparent electrode 23 and a p-type electrode 25 are deposited on the p-type nitride semiconductor layer 21. And, an n-type electrode 27 is formed on an exposed upper part of the n-type nitride semiconductor layer 21.

In the semiconductor LED 10 having the above configurations, once a voltage is applied through the p-type electrode 25 and the n-type electrode 27, electrons and holes are introduced into active layer 19 from the n-type nitride semiconductor layer 17 and the p-type nitride semiconductor layer 21. As a result, re-coupling between the electrons and the holes is performed, and the semiconductor LED 10 emits light.

The conventional method for fabricating the semiconductor LED will be explained.

Firstly, the buffer layer 13 having a low temperature is initially grown on the sapphire substrate 11 so as to grow a hetero semiconductor material (GaN). Then, the temperature is increased to crystallize the buffer layer 13.

Then, on the buffer layer 13, grown are the epitaxial layer 15 formed of an un-doped GaN semiconductor material, and the n-type nitride semiconductor layer 17 formed of n-type GaN.

Then, the active layer 19 having a multi quantum well (MQW) structure is grown on the n-type nitride semiconductor layer 17 at a temperature lower than a growth temperature of the n-type nitride semiconductor layer 17.

Then, the temperature is increased to form, on the active layer 19, the p-type nitride semiconductor layer 21 formed of p-type GaN.

Then, a transparent conductive material is deposited on the p-type nitride semiconductor layer 21 by an E-beam deposition method or a sputtering method, thereby forming the transparent electrode 23.

Then, the transparent electrode 23, the p-type nitride semiconductor layer 21, the active layer 19 and the n-type nitride semiconductor layer 17 are partially mesa-etched, thereby partially exposing the n-type nitride semiconductor layer 17.

Then, the p-type electrode 25 and the n-type electrode 27 are formed on the transparent electrode 23 and the n-type nitride semiconductor layer 17 exposed by the mesa-etching, respectively. Accordingly, the semiconductor LED 10 is fabricated.

However, the conventional semiconductor LED and the method for fabricating the same have the following problems.

Firstly, the GaN having the same crystallinity of a dense hexagonal structure as the sapphire has a different lattice constant from the sapphire. Accordingly, in case of growing the GaN on the sapphire substrate so as to form the epitaxial layer, the low temperature buffer layer is formed and then crystallized GaN is grown.

However, even if the GaN is grown by this method, a plurality of crystalline defects (D) occur as shown in FIG. 2. These crystalline defects (D) spread up to the active layer, resulting in decreasing light emitting efficiency.

Especially, when growing the GaN on the sapphire substrate, a plurality of crystalline defects occur by lattice mismatching even if a low temperature buffer layer is initially used. This may consecutively spread up to the n-type GaN layer and the active layer.

Secondly, after when growing the n-type GaN layer to form the GaN epitaxial layer of the LED, concave bowing of a wafer may occur. In this state, the active layer may grow to lower uniformity of light emitting, and to reduce a wavelength yield.

### SUMMARY OF THE INVENTION

Therefore, an object of the present invention is to provide a semiconductor light emitting diode (LED) capable of having an excellent film quality by preventing a crystalline defect occurring when an epitaxial layer of the LED grows, capable of having improved wavelength uniformity by preventing bowing of a wafer, and capable of enhancing a chip yield, and a method for fabricating the same.

Another object of the present invention is to provide a semiconductor light emitting diode (LED) capable of fabricating not only a high voltage LED having high light emitting efficiency, but also an LED which can enhance a yield by using a large substrate, and a method for fabricating the same.

To achieve these and other advantages and in accordance with the purpose of the present invention, as embodied and broadly described herein, there is provided a semiconductor light emitting diode (LED), comprising: a substrate; an epitaxial layer formed on the substrate, and consisting of a plurality of crystalline semiconductor layers and an amorphous layer interposed between the plurality of crystalline semiconductor layers; an n-type nitride semiconductor layer formed on the epitaxial layer; an active layer formed on the n-type nitride semiconductor layer; a p-type nitride semiconductor layer formed on the active layer; and a p-type electrode and an n-type electrode formed on the p-type nitride semiconductor layer and the n-type nitride semiconductor layer, respectively.

To achieve these and other advantages and in accordance with the purpose of the present invention, as embodied and broadly described herein, there is also provided a method for fabricating a semiconductor light emitting diode (LED), the method comprising: forming a crystalline nitride semiconductor layer on a substrate; forming an amorphous layer and a crystalline nitride semiconductor layer on the nitride semiconductor layer; forming an n-type nitride semiconductor layer on the crystalline nitride semiconductor layer; forming an active layer on the n-type nitride semiconductor layer; and forming a p-type nitride semiconductor layer on the active layer.

The semiconductor LED and the method for fabricating the same according to the present invention may have the following advantages.

Firstly, an amorphous layer may be made to grow while growing an epitaxial layer formed of an un-doped GaN-based material. This may allow the epitaxial layer to grow again centering around defect regions having high active energy. As a result, growth defects are prevented.

Secondly, a condition for forming the amorphous layer is different from a general GaN forming condition (i.e., a case of a low temperature). The amorphous layer for attenuating bowing of a wafer in an opposite direction to a bent direction is inserted between the crystalline nitride semiconductor layers during the GaN growth. This may allow bowing of a wafer to be more decreased than in a general GaN growing condition at the time of growing the active layer. Accordingly, wavelength uniformity may be enhanced, and the LED may have an improved yield.

Thirdly, while un-doped GaN-based nitride semiconductor layers which constitute the epitaxial layer of the LED are grown, the amorphous layer is interposed between the semiconductor layers. This may improve film quality by decreasing growth defects, and may enhance light emitting efficiency.

Fourthly, while the un-doped GaN-based nitride semiconductor layers which constitute the epitaxial layer of the LED are grown, the amorphous layer is interposed between the semiconductor layers. This may reduce bowing of a wafer to prevent breaking of the substrate at a subsequent processing, thereby enhancing the entire processing yield.

Fifthly, bowing of a wafer occurring when a large substrate is used may be prevented. Accordingly, a large substrate may be used.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a sectional view showing a structure of a semiconductor light emitting diode (LED) in accordance with the related art;

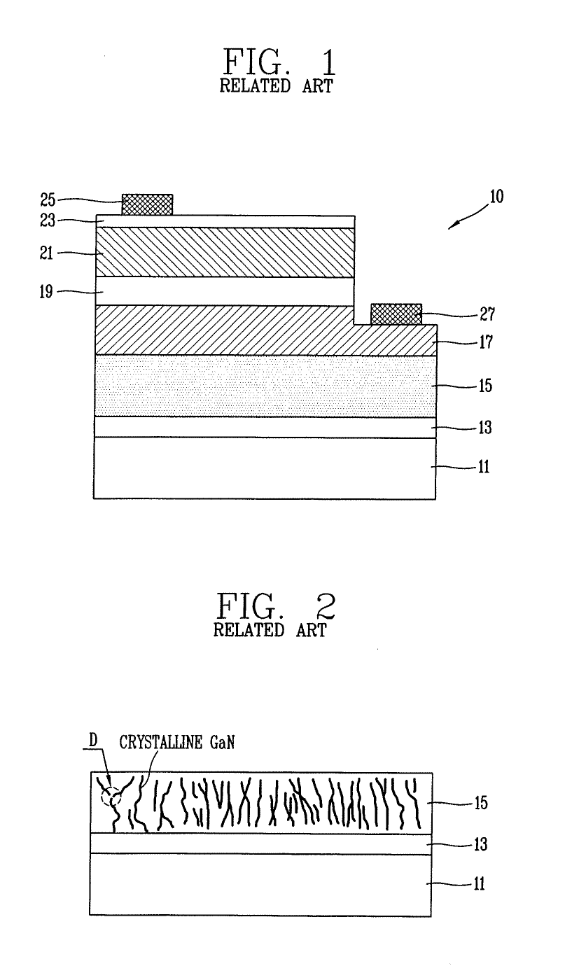

FIG. 2 is a sectional view schematically showing growth defects occurring when an epitaxial layer of a semiconductor LED grows in accordance with the related art;

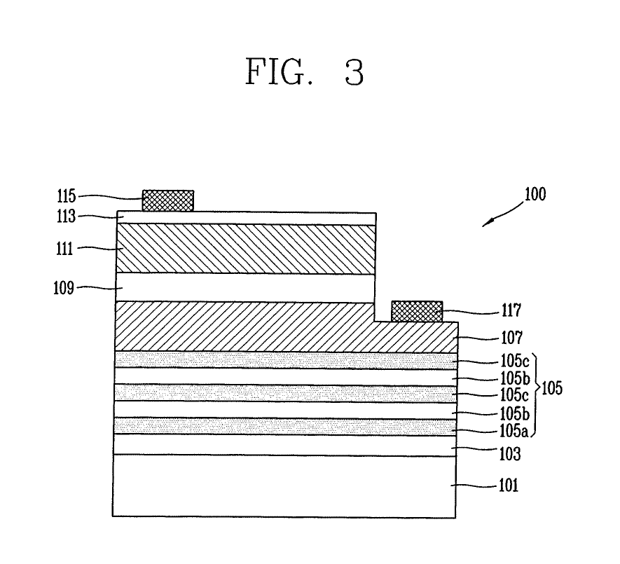

FIG. 3 is a sectional view showing a structure of a semiconductor light emitting diode (LED) according to the present invention;

FIGS. 4A to 4F are sectional views showing processes for fabricating a semiconductor light emitting diode (LED) according to the present invention;

FIG. 5 is a sectional view schematically showing that growth defects are prevented by inserting an amorphous layer between crystalline nitride semiconductor layers while an epitaxial layer of a semiconductor light emitting diode (LED) grows according to the present invention; and

FIG. 6 is a graph comparing electrical characteristics of a semiconductor LED according to the present invention with those of a semiconductor LED in accordance with the conventional art.

### DETAILED DESCRIPTION OF THE INVENTION

Description will now be given in detail of the present invention, with reference to the accompanying drawings.

For the sake of brief description with reference to the drawings, the same or equivalent components will be provided with the same reference numbers, and description thereof will not be repeated.

Hereinafter, a semiconductor light emitting diode (LED) according to a preferred embodiment of the present invention will be explained in more detail with reference to the attached drawings.

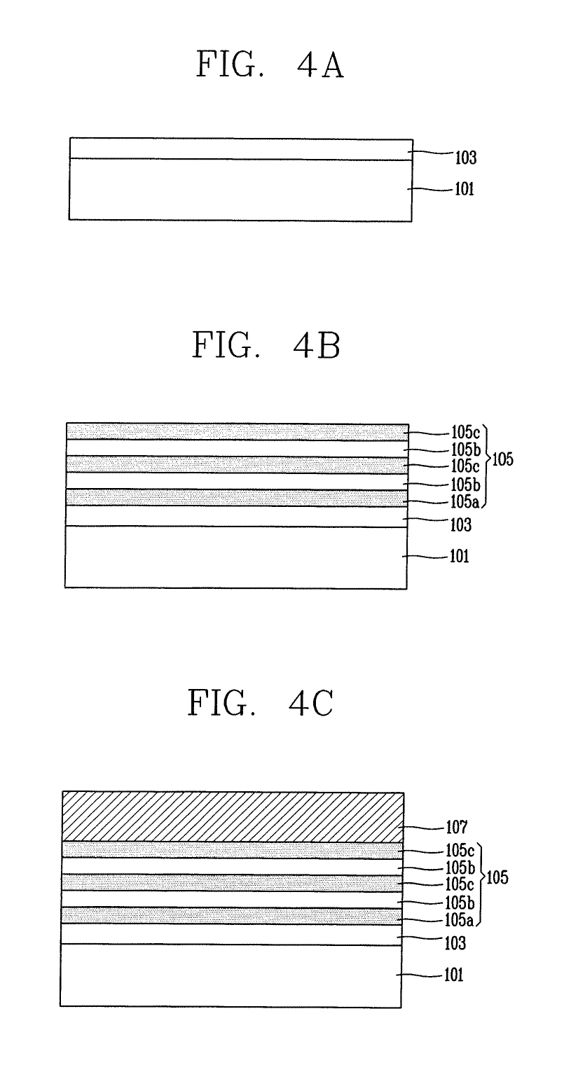

FIG. 3 is a sectional view showing a structure of a semiconductor light emitting diode (LED) according to the present invention.

As shown in FIG. 3, the semiconductor LED 100 according to the present invention comprises a sapphire substrate 101, a buffer layer 103 formed on the sapphire substrate 101, an epitaxial layer 105 having one or more laminated structures of an un-doped GaN-based crystalline first semiconductor layer 105a, an amorphous layer 105b formed on the first semiconductor layer 105a, and an un-doped GaN-based crystalline second semiconductor layer 105c, an n-type nitride semiconductor layer 107, an active layer 109 having a multi quantum well structure, and a p-type nitride semiconductor layer 111.

As some regions of the p-type nitride semiconductor layer 111 and the active layer 109 are removed by mesa-etching, an upper surface of the n-type nitride semiconductor layer 107 is partially exposed.

The buffer layer 103 is grown on the sapphire substrate 101 so as to enhance lattice matching between the sapphire substrate 101 and the n-type nitride semiconductor layer 107. Here, the buffer layer 103 is grown to have a thickness of several tens˜several hundreds of □ at a temperature of about 500□600□ by using GaN, AlN, InGaN, etc.

The epitaxial layer 105 has a laminated structure of the un-doped GaN-based crystalline first semiconductor layer 105a, at least one amorphous layer 105b formed on the first semiconductor layer 105a, and the un-doped GaN-based crystalline second semiconductor layer 105c. That is, the amorphous layer 105b is interposed between the crystalline semiconductor layers 105a and 105c of the epitaxial layer 105. Here, the crystalline semiconductor layers 105a and 105c may be formed by an epitaxial growing method using a metal organic chemical vapor deposition (MOCVD) device. The crystalline first semiconductor layer 105a is grown to have a constant thickness at a temperature of about 1,000□1,200□, and the amorphous layer 105b is deposited to have a thickness of about 10□100 nm at a temperature of about 400□700□. As the amorphous layer 105b, may be used a semiconductor material of InₓAl_{y}Ga(_{1-x-y})N (here, 1-x-y>0).

The amorphous layer 105b is grown while growing the crystalline semiconductor layers 105a and 105c. This may allow the epitaxial layer 105 to grow again centering around defect regions having high active energy. This may prevent growth defects. A condition for forming the amorphous layer is different from a general GaN layer forming condition (i.e., a case of a low temperature). The amorphous layer 105b for attenuating bowing of a wafer in an opposite direction to a bent direction is inserted between the crystalline semiconductor layers 105a and 105c while the crystalline semiconductor layers 105a and 105c are grown. This may allow bowing of a wafer to be more decreased than in a general condition for growing nitride semiconductor layers formed of GaN at the time of growing the active layer 109. Accordingly, wavelength uniformity is enhanced, and the LED 100 has an improved yield.

The n-type nitride semiconductor layer 107, the p-type nitride semiconductor layer 111, and the active layer 109 may be semiconductor materials having a composition formula of AlₓIn_{y}Ga(_{1-x-y})N (here, 0≦x≦1, 0≦y≦1, 0≦x+y≦1). More concretely, the n-type nitride semiconductor layer 107 may be formed of a GaN layer or a Ga/AlGaN layer doped with n-type conductive impurities. The active layer 109 may be formed of an un-doped InGaN layer having a multi quantum well structure. And, the p-type nitride semiconductor layer 111 may be formed of a GaN layer or a Ga/AlGaN layer doped with p-type conductive impurities.

The n-type nitride semiconductor layer 107, the p-type nitride semiconductor layer 111, and the active layer 109 may be formed by an epitaxial growing method using a metal organic chemical vapor deposition (MOCVD) device. The n-type nitride semiconductor layer 107 is grown to have a thickness of several μm at a temperature of about 900□1,100□, and the active layer 109 is grown to have a thickness of about 1,000□ at a temperature of about 700□900□. The p-type nitride semiconductor layer 111 is grown to have a thickness of several thousands of □ so as not to badly influence on the active layer 109.

A transparent electrode 113 and a p-type electrode 115 are formed on the p-type nitride semiconductor layer 111 having not been etched by the mesa-etching process. And, an n-type electrode 117 is formed on the n-type nitride semiconductor layer 107 having been exposed by the etching process.

In the semiconductor LED 100 having the above configurations, once a voltage is applied through the p-type electrode 115 and the n-type electrode 117, electrons and holes are introduced into the active layer 109 from the n-type nitride semiconductor layer 107 and the p-type nitride semiconductor layer 111. As a result, re-coupling between the electrons and the holes is performed, and the semiconductor LED 100 emits light.

Hereinafter, a method for fabricating a semiconductor light emitting diode (LED) according to the present invention will be explained in more detail with reference to the attached drawings.

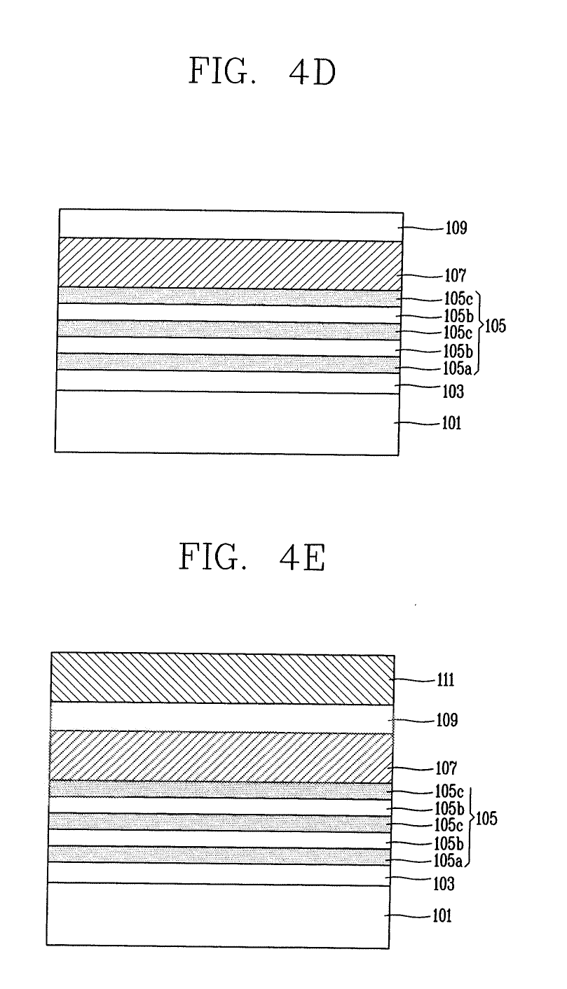

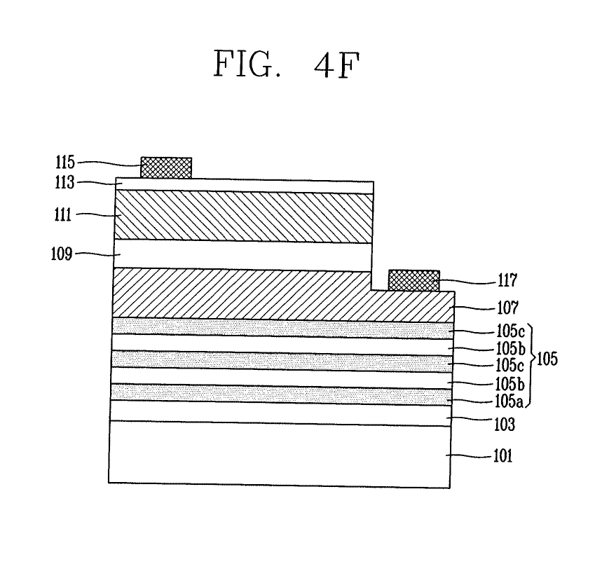

FIGS. 4A to 4F are sectional views showing processes for fabricating a semiconductor light emitting diode (LED) according to the present invention, and FIG. 5 is a sectional view schematically showing that growth defects are prevented by inserting an amorphous layer between crystalline nitride semiconductor layers while an epitaxial layer of a semiconductor light emitting diode (LED) grows according to the present invention.

As shown in FIG. 4A, the sapphire substrate 101 undergoes a heat processing at a high temperature (e.g., 1,000□1,200□) under a hydrogen (H₂) atmosphere so as to remove impurities.

Then, the buffer layer 103 is formed on the sapphire substrate 101 at a low temperature (e.g., 500□600□).

Then, the buffer layer 103 is crystallized in a state that the temperature has been increased to about 900□1,100□. Here, the buffer layer 103 is grown on the sapphire substrate 101 so as to enhance lattice matching between the sapphire substrate 101 and the n-type nitride semiconductor layer 107. The buffer layer 103 is formed by growing GaN, AlN, InGaN, etc. to have a thickness of several tens˜several hundreds of □ at a temperature of about 500□600□.

As shown in FIG. 4B, the buffer layer 103 is crystallized, and then the epitaxial layer 105 is grown to have a thickness of several μm. Here, the epitaxial layer 105 has a laminated structure of an un-doped GaN-based crystalline first semiconductor layer 105a, at least one amorphous layer 105b formed on the first semiconductor layer 105a, and an un-doped GaN-based crystalline second semiconductor layer 105c. That is, the amorphous layer 105b is interposed between the crystalline semiconductor layers 105a and 105c of the epitaxial layer 105.

Hereinafter, a method for fabricating the epitaxial layer 105 of the semiconductor LED will be explained in more detail with reference to FIG. 4B.

As shown in FIG. 4B, the buffer layer 103 is crystallized, and then the un-doped GaN-based crystalline first semiconductor layer 105a is grown on the buffer layer 103. Here, the crystalline semiconductor layers 105a and 105c may be formed by an epitaxial growing method using a metal organic chemical vapor deposition (MOCVD) device. The crystalline first semiconductor layer 105a is grown to have a constant thickness at a temperature of about 1,000□1,200 □.

Then, the amorphous layer 105b having a different growing condition is deposited, on the crystalline first semiconductor layer 105a, to have a thickness of about 10□100 nm at a temperature of about 400□700□. As the amorphous layer 105b, may be used a semiconductor material of InₓAl_{y}Ga(_{1-x-y})N (here, 1-x-y>0).

Then, the un-doped GaN-based crystalline second semiconductor layer 105c is grown on the amorphous layer 105b. Here, the crystalline second semiconductor layer 105c may be formed by an epitaxial growing method using a metal organic chemical vapor deposition (MOCVD) device. The crystalline second semiconductor layer 105c is grown to have a constant thickness at a temperature of about 1,000□1,200 □.

The lamination structure of the amorphous layer 105b and the un-doped crystalline second semiconductor layer 105c may be formed to be repeated at least one time.

The amorphous layer 105b is grown while growing the crystalline semiconductor layers 105a and 105c. This may allow the epitaxial layer 105 to grow again centering around defect regions having high active energy as shown in FIG. 5. As a result, growth defects are prevented. A condition for forming the amorphous layer 105b is different from a general GaN layer forming condition (i.e., a case of a low temperature). The amorphous layer 105b for attenuating bowing of a wafer in an opposite direction to a bent direction is inserted between the crystalline semiconductor layers 105a and 105c while the crystalline semiconductor layers 105a and 105c are grown. This may allow bowing of a wafer to be more decreased than in a general condition for growing nitride semiconductor layers formed of general GaN at the time of growing the active layer 109. Accordingly, wavelength uniformity is enhanced, and the LED 100 has an improved yield.

As shown in FIG. 4C, the n-type nitride semiconductor layer 107 is grown on the epitaxial layer 105 so as to have a thickness of several μm at a temperature of about 900□1,100□. Here, the n-type nitride semiconductor layer 107 may be formed of semiconductor materials having a composition formula of AlₓIn_{y}Ga(_{1-x-y})N (here, 0≦x≦1, 0≦y≦1, 0≦x+y≦1). More concretely, the n-type nitride semiconductor layer 107 may be formed of a GaN layer or a Ga/AlGaN layer doped with n-type conductive impurities. The n-type nitride semiconductor layer 107 may be formed by an epitaxial growing method using a metal organic chemical vapor deposition (MOCVD) device.

As shown in FIG. 4D, the active layer 109 is grown on the n-type nitride semiconductor layer 107 so as to have a thickness of about 1,000□ at a temperature of about 700□900□. Here, the active layer 109 may be formed of semiconductor materials having a composition formula of AlₓIn_{y}Ga(_{1-x-y})N (here, 0≦x≦1, 0≦y≦1, 0≦x+y≦1). The active layer 109 may be formed of an un-doped InGaN layer having a multi quantum well structure. And, the active layer 109 may be formed by an epitaxial growing method using a metal organic chemical vapor deposition (MOCVD) device.

As shown in FIG. 4E, the p-type nitride semiconductor layer 111 is grown on the active layer 109 to have a thickness of several thousands of □ so as not to badly influence on the active layer 109. Here, the p-type nitride semiconductor layer 111 may be formed of semiconductor materials having a composition formula of AlₓIn_{y}Ga(_{1-x-y})N (here, 0≦x≦1, 0≦y≦1, 0≦x+y≦1). The p-type nitride semiconductor layer 111 may be formed of a GaN layer or a Ga/AlGaN layer doped with p-type conductive impurities. The p-type nitride semiconductor layer 111 may be formed by an epitaxial growing method using a metal organic chemical vapor deposition (MOCVD) device.

As shown in FIG. 4F, a transparent conductive material is deposited on the p-type nitride semiconductor layer 111 by a sputtering method, thereby forming a transparent electrode 113.

Then, the transparent electrode 113, the p-type nitride semiconductor layer 111, the active layer 109, and the n-type nitride semiconductor layer 107 are partially mesa-etched, thereby exposing some regions of the n-type nitride semiconductor layer 107. As aforementioned, the transparent electrode 113 may be formed before the mesa-etching. Alternatively, after the mesa-etching, the transparent electrode 113 may be formed on the p-type nitride semiconductor layer 111 having not been etched by the etching process.

Then, the p-type electrode 115 and the n-type electrode 117 are formed on the transparent electrode 113 and the n-type nitride semiconductor layer 107 exposed by the mesa-etching, thereby fabricating the semiconductor LED 100.

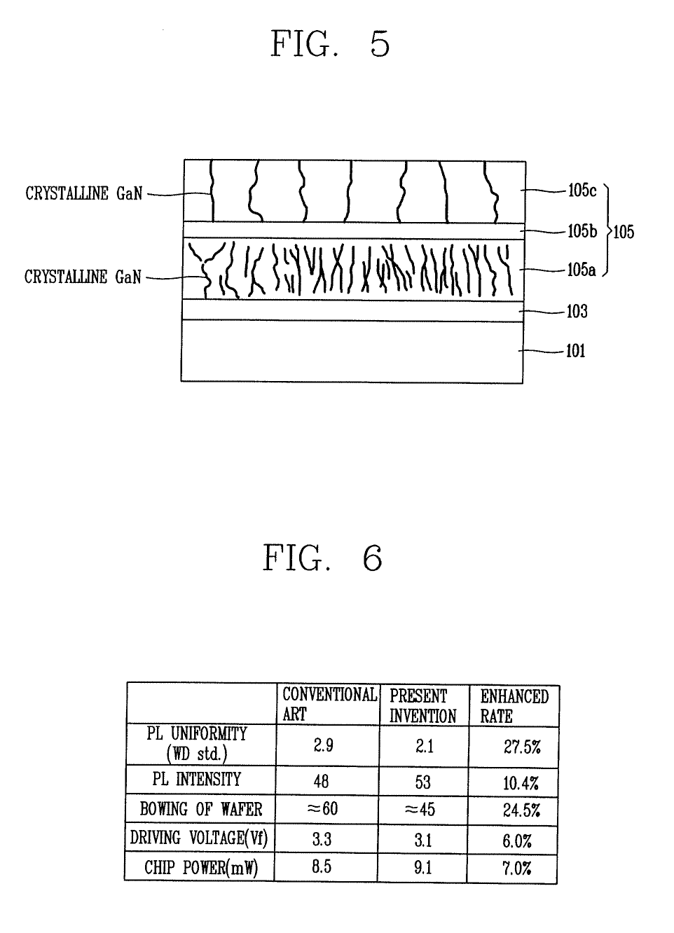

Hereinafter, electrical characteristics of the semiconductor LED according to the present invention will be explained with reference to FIG. 6.

FIG. 6 is a graph comparing electrical characteristics of the semiconductor LED according to the present invention with those of a semiconductor LED in accordance with the conventional art.

Referring to FIG. 6, the conventional LED showed PL uniformity of about 2.9, whereas the LED of the present invention showed PL uniformity of about 2.1. More concretely, the LED of the present invention having the epitaxial layer 105 consisting of the un-doped GaN-based crystalline first semiconductor layer 105a, at least one amorphous layer 105b formed on the first semiconductor layer 105a, and the un-doped GaN-based crystalline second semiconductor layer 105c showed PL uniformity more enhanced than the conventional one by about 27.5%.

Referring to FIG. 6, the conventional LED showed PL intensity of about 48, whereas the LED of the present invention showed PL intensity of about 53. More concretely, the LED of the present invention having the epitaxial layer 105 consisting of the un-doped GaN-based crystalline first semiconductor layer 105a, at least one amorphous layer 105b formed on the first semiconductor layer 105a, and the un-doped GaN-based crystalline second semiconductor layer 105c showed PL intensity more enhanced than the conventional one by about 10.4%.

Referring to FIG. 6, the conventional LED showed wafer bowing of about 60, whereas the LED of the present invention showed wafer bowing of about 45. More concretely, the LED of the present invention having the epitaxial layer 105 consisting of the un-doped GaN-based crystalline first semiconductor layer 105a, at least one amorphous layer 105b formed on the first semiconductor layer 105a, and the un-doped GaN-based crystalline second semiconductor layer 105c showed wafer bowing more enhanced than the conventional one by about 24.5%.

Referring to FIG. 6, the conventional LED showed a driving voltage (Vf) of about 3.3, whereas the LED of the present invention showed a driving voltage of about 3.1. More concretely, the LED of the present invention having the epitaxial layer 105 consisting of the un-doped GaN-based crystalline first semiconductor layer 105a, at least one amorphous layer 105b formed on the first semiconductor layer 105a, and the un-doped GaN-based crystalline second semiconductor layer 105c showed a driving voltage more enhanced than the conventional one by about 6.0%.

Referring to FIG. 6, the conventional LED showed chip power (mW) of about 8.5, whereas the LED of the present invention showed chip power of about 9.1. More concretely, the LED of the present invention having the epitaxial layer 105 consisting of the un-doped GaN-based crystalline first semiconductor layer 105a, at least one amorphous layer 105b formed on the first semiconductor layer 105a, and the un-doped GaN-based crystalline second semiconductor layer 105c showed chip power more enhanced than the conventional one by about 7.0%.

The semiconductor LED and the method for fabricating the same according to the present invention may have the following advantages.

Firstly, the amorphous layer may be made to grow while growing the epitaxial layer formed of an un-doped GaN-based material. This may allow the epitaxial layer to grow again centering around defect regions having high active energy. As a result, growth defects may be prevented.

Secondly, a condition for forming the amorphous layer is different from a general GaN forming condition (i.e., a case of a low temperature). The amorphous layer for attenuating bowing of a wafer in an opposite direction to a bent direction is inserted between the crystalline nitride semiconductor layers during the GaN growth. This may allow bowing of a wafer to be more decreased than in a general GaN growing condition at the time of growing the active layer. Accordingly, wavelength uniformity may be enhanced, and the LED may have an improved yield.

Thirdly, while the un-doped GaN-based nitride semiconductor layers which constitute the epitaxial layer of the LED are grown, the amorphous layer is interposed between the crystalline nitride semiconductor layers. This may improve film quality by decreasing growth defects, and may enhance light emitting efficiency.

Fourthly, while the un-doped GaN-based nitride semiconductor layers which constitute the epitaxial layer of the LED are grown, the amorphous layer is interposed between the crystalline nitride semiconductor layers. This may reduce bowing of a wafer to prevent breaking of the substrate at a subsequent processing, thereby enhancing the entire processing yield.

Fifthly, bowing of a wafer occurring when a large substrate is used may be prevented. Accordingly, a large substrate may be used.

The foregoing embodiments and advantages are merely exemplary and are not to be construed as limiting the present disclosure. The present teachings can be readily applied to other types of apparatuses. This description is intended to be illustrative, and not to limit the scope of the claims. Many alternatives, modifications, and variations will be apparent to those skilled in the art. The features, structures, methods, and other characteristics of the exemplary embodiments described herein may be combined in various ways to obtain additional and/or alternative exemplary embodiments.

As the present features may be embodied in several forms without departing from the characteristics thereof, it should also be understood that the above-described embodiments are not limited by any of the details of the foregoing description, unless otherwise specified, but rather should be construed broadly within its scope as defined in the appended claims, and therefore all changes and modifications that fall within the metes and bounds of the claims, or equivalents of such metes and bounds are therefore intended to be embraced by the appended claims.

What is claimed is:

1. A semiconductor light emitting diode (LED), comprising:
a substrate;
an epitaxial layer formed on the substrate, and consisting of a plurality of crystalline semiconductor layers and an amorphous layer interposed between the plurality of crystalline semiconductor layers;
an n-type nitride semiconductor layer formed on the epitaxial layer;
an active layer formed on the n-type nitride semiconductor layer;
a p-type nitride semiconductor layer formed on the active layer; and
a p-type electrode and an n-type electrode formed on the p-type nitride semiconductor layer and the n-type nitride semiconductor layer, respectively.

2. The semiconductor light emitting diode of claim 1, wherein the amorphous layer of the epitaxial layer is interposed between the plurality of crystalline semiconductor layers.

3. The semiconductor light emitting diode of claim 1, wherein the amorphous layer is formed to have a thickness of 10□100 nm.

4. The semiconductor light emitting diode of claim 1, wherein the amorphous layer is formed of semiconductor materials of InₓAl_{y}Ga(_{1-x-y})N (here, 1-x-y>0).

5. The semiconductor light emitting diode of claim 1, wherein the epitaxial layer has at least one laminated structure of a crystalline semiconductor layer formed on the buffer layer, an amorphous layer formed on the crystalline semiconductor layer, and a crystalline semiconductor layer formed on the amorphous layer.

6. The semiconductor light emitting diode of claim 1, wherein the n-type nitride semiconductor layer, the p-type nitride semiconductor layer, and the active layer are formed of semiconductor materials having a composition formula of AlₓIn_{y}Ga(_{1-x-y})N (here, 0≦x≦1, 0≦y≦1, 0≦x+y≦1).

7. A method for fabricating a semiconductor light emitting diode (LED), the method comprising:
forming a crystalline nitride semiconductor layer on a substrate;
forming an amorphous layer and a crystalline nitride semiconductor layer on the nitride semiconductor layer;
forming an n-type nitride semiconductor layer on the crystalline nitride semiconductor layer;
forming an active layer on the n-type nitride semiconductor layer; and
forming a p-type nitride semiconductor layer on the active layer.

8. The method of claim 7, wherein the amorphous layer is interposed between the plurality of crystalline semiconductor layers.

9. The method of claim 7, wherein the amorphous layer is formed to have a thickness of 10□100 nm.

10. The method of claim 7, wherein the amorphous layer is formed of semiconductor materials of InₓAl_{y}Ga(_{1-x-y})N (here, 1-x-y>0).

11. The method of claim 7, wherein the n-type nitride semiconductor layer, the p-type nitride semiconductor layer, and the active layer are formed of semiconductor materials having a composition formula of AlₓIn_{y}Ga(_{1-x-y})N (here, 0≦x≦1, 0≦y≦1, 0≦x+y≦1).

12. The method of claim 7, wherein the step of forming an amorphous layer and a crystalline nitride semiconductor layer on the nitride semiconductor layer is performed at least one time.

13. The method of claim 7, further comprising forming a p-type electrode and an n-type electrode on the p-type nitride semiconductor layer and the n-type nitride semiconductor layer, respectively.

14. The method of claim 13, further comprising forming a transparent electrode between the p-type nitride semiconductor layer and the p-type electrode.

15. The method of claim 7, further comprising forming a buffer layer between the substrate and the crystalline nitride semiconductor layer.
